(19) United States
(12) Patent Application Publication
(10) Pub. No.: US 2025/0037735 A1
(43) Pub. Date: Jan. 30, 2025

(54) DIGITAL AUDIO MEASUREMENT SYSTEMS AND METHOD

(71) Applicant: Sameer KUMAR, San Diego, CA (US)

(72) Inventor: Sameer KUMAR, San Diego, CA (US)

(21) Appl. No.: 18/716,722

(22) PCT Filed: Oct. 12, 2023
(86) PCT No.: PCT/US2023/076686

§ 371 Date: Jun. 5, 2024

Related U.S. Application Data
(60) Provisional application No. 63/415,613, filed on Oct. 12, 2022.

(51) Int. Cl. G10L 25/60; G10L 19/022

(52) U.S. Cl. CPC G10L 25/60; G10L 19/022

(57) ABSTRACT

Systems and methods for digital audio measurement such as perceived loudness. An example of the method includes dividing, by a processor, a digital audio file into a plurality of blocks in a time sequence at a first time length; determining, by the processor, a respective Loudness Units relative to Full Scale (LUFS) for each block; determining, by the processor, a difference between the LUFS of each block with a reference value; and generating, by the processor, an indicator from one or more of the differences of the plurality of blocks within a second time length.

### CROSS REFERENCE

The present application claim priority over U.S. provisional patent application No. 63/415,613, entitled “DIGITAL AUDIO MEASUREMENT SYSTEMS AND METHOD”, filed on Oct. 12, 2022, which is incorporated by reference into the Detailed Description herein below in its entirety.

### TECHNICAL FIELD

Example embodiments relate to audio file processing, in particular, to methods and systems for measuring perceived loudness of audio files.

### BACKGROUND

Perception of loudness of an audio file may be measured by Root Mean Square (RMS), Loudness Range (LRA), and Loudness Units relative to Full Scale (LUFS). RMS is defined by the average levels of loudness throughout an audio file. LRA measures loudness, and distribution throughout an audio file, determines dynamics properties of an audio file. The lower the number, the less dynamics. LUFS is a measurement of psychoacoustic perception of loudness. For example, songs with the same reported LUFS (Loudness Units relative to Full Scale) may actually be perceived as being drastically different in loudness.

Streaming platforms, broadcast authorities, film and television production companies, music producers, and more all rely on integrated LUFS for loudness evaluation. Integrated LUFS continues accounting for loudness information over time and updates the average LUFS value. The problem is that LUFS can be an insufficient indicator of perceived loudness.

Despite being of different durations, peak levels, and maximum momentary loudness, the waveforms that would have the same LUFS would actually have different perceived loudness. For example, despite having the same LUFS, two songs may be dynamically quite different: one song is quite compressed while the other is comparably more dynamic. Despite these differences, conventional loudness measurement schemes fail to provide an accurate indication of perceived volume.

Consumer listening experiences may be greatly degraded if songs are compiled or sequenced using conventional loudness measurement schemes, possibly increasing skip rates for some songs more than others.

### SUMMARY

An example embodiment is a method which includes dividing, by a processor, a digital audio file into a plurality of blocks in a time sequence at a first time length; determining, by the processor, a respective Loudness Units relative to Full Scale (LUFS) for each block; determining, by the processor, a difference between the LUFS of each block with a reference value; and generating, by the processor, an indicator from one or more of the differences of the plurality of blocks within a second time length.

In an example embodiment of any of the above methods, the method further comprises processing, by the processor, the digital audio file based on the indicator among a plurality of audio files.

In an example embodiment of any of the above methods, processing the digital audio file comprises rendering the audio file for playback among the plurality of the audio files.

In an example embodiment of any of the above methods, processing the digital audio file comprises sequencing or grouping of the audio file for among the plurality of digital audio files.

In an example embodiment of any of the above methods, the first time length is 400 ms.

In an example embodiment of any of the above methods, the first time length is 50 ms.

In an example embodiment of any of the above methods, the second time length is 3 seconds.

In an example embodiment of any of the above methods, the second time length is 10 seconds.

In an example embodiment of any of the above methods, the second time length is an entire duration of the digital audio file.

In an example embodiment of any of the above methods, each block overlaps with a next block in the time sequence by 75% of the first time length.

In an example embodiment of any of the above methods, the next block starts 100 ms from a start time of each block.

In an example embodiment of any of the above methods, values of the LUFS are ungated, and the reference value comprises the LUFS of the subsequent block of each block.

In an example embodiment of any of the above methods, the reference value comprises a baseline value of the digital audio file which is an average LUFS in a third time length.

In an example embodiment of any of the above methods, the third period is 3 seconds.

In an example embodiment of any of the above methods, the method further comprises comparing the LUFS of each block to the baseline value and determining a difference between the LUFS for each block and the baseline value, wherein the LUFS is gated.

In an example embodiment of any of the above methods, the method further comprises separately generating a first average of the difference between the baseline value and LUFS values greater than the baseline value, and a second average of the difference between the baseline value and the LUFS values lower than the baseline value.

In an example embodiment of any of the above methods, the first and second average values serve as indicators of the distribution of loudnesses of the digital audio file.

In an example embodiment of any of the above methods, the indicator is a mean value of the one or more of the differences.

In an example embodiment of any of the above methods, the indicator indicates a relative level of perceived impact from the digital audio file.

In an example embodiment of any of the above methods, the indicator indicates a relative level of perceived real impact value from the digital audio file.

In an example embodiment of any of the above methods, the indicator indicates a relative level of perceived textural impact value from the digital audio file.

In an example embodiment of any of the above methods, the indicator indicates a relative level of local organized clusters (LOCL) of the digital audio file.

In an example embodiment of any of the above methods, the indicator comprises one or more local organized clusters (LOCL) analysis comprising one or more of, within the second time length: a Standard Deviation of LUFS, a measures of average LUFS, a comparative analysis of LUFS, or a distribution analysis of LUFS.

In an example embodiment of any of the above methods, processing the digital audio file comprises re-mastering the digital audio file with less compression and saturation to allow for more momentary dynamic variance.

In an example embodiment of any of the above methods, the method further comprises compiling a playlist comprising the plurality of audio files.

In an example embodiment of any of the above methods, the digital audio file contains PCM audio data.

In an example embodiment of any of the above methods, the method further comprises outputting or visualizing the indicator.

In an example embodiment of any of the above methods, the indicator is generated in real time.

In an example embodiment of any of the above methods, the audio file is associated with a user's preference comprising a user-defined mood tag.

In an example embodiment of any of the above methods, LOCL separately indicate one or more of: frequency bands in less than 100 Hz, between 2 KHz and 5 KHz, or greater than 12 KHz of the digital audio file.

In an example embodiment of any of the above methods, processing the digital audio file comprises normalizing the digital audio file using attenuation or amplification.

In an example embodiment of any of the above methods, processing the digital audio file comprises spectral equalization or spectral dynamics for increasing or decreasing perceived loudness. For example, processing the digital audio file comprises modifying the digital audio file so that the indicator matches or is within a target range, such as a target range of RIV, TIV or LOCL of the selected audio files.

In an example embodiment of any of the above methods, spectral equalization or spectral dynamics comprises one or more of: resonance suppression, high-frequency limiting, or low-frequency compression or expansion.

In an example embodiment of any of the above methods, the method further comprises playing back the digital audio file at a user-defined level on a digital streaming platform.

In an example embodiment of any of the above methods, the method further comprises filtering, by the processor, the digital audio file in one or more frequency bands.

In an example embodiment of any of the above methods, the one or more selected frequency bands comprise one or more of: a low-frequency band which is below 100 Hz, a mid-frequency band which is between 100 Hz and 2000 Hz, a high-frequency band between 2000 Hz and 5000 Hz, or a sibilance frequency band between 5000 Hz and 12000 Hz.

In an example embodiment of any of the above methods, the indicator comprises one or more of: a low-frequency indicator for the low-frequency band, a mid-frequency indicator for the mid-frequency band, a high-frequency indicator for the high-frequency band, or a sibilance indicator for the sibilance frequency band.

In an example embodiment of any of the above methods, the method further comprises processing, by the processor, the digital audio file based on the one or more of: the low-frequency indicator, the mid-frequency indicator, the high-frequency indicator, or the sibilance indicator.

In an example embodiment of any of the above methods, processing the digital audio file comprises normalizing the digital audio file using attenuation or amplification.

In an example embodiment of any of the above methods, processing the digital audio file comprises spectral equalization or spectral dynamics for increasing or decreasing perceived loudness, envelope filtering, transient suppression, transient enhancement, and frequency-based dynamics processing comprising high-frequency limiting or high-frequency expansion, and multiband compression or expansion.

In an example embodiment of any of the above methods, spectral equalization or spectral dynamics comprises one or more of: resonance suppression, high-frequency limiting, or low-frequency compression or expansion.

In an example embodiment of any of the above methods, the method further comprises playing back the digital audio file at a user-defined level on a digital streaming platform.

In an example embodiment of any of the above methods, the method further comprises processing digital audio files with one or more user defined parameters comprising bass intensity, high-frequency density, sibilance, perceived loudness, perceived impact, perceived textural impact, macrodynamic profile, tempo or beats-per-minute, genre or subgenre, lyrical content, mood defined by the user or defined by a combination of measured characteristics, key, spectral characteristics comprising bass intensity, midrange intensity, high-frequency density, and sibilance, and dynamics characteristics.

In an example embodiment of any of the above methods, the method further comprises processing the digital audio file comprises sequencing or grouping of the digital audio file among the plurality of digital audio files based on Real Impact Values, Textural Impact Value, or local organized clusters (LOCL) quiet or loud markers of the plurality of the digital audio files.

In an example embodiment of any of the above methods, the method further comprises associating the digital audio file for integration with an external reference based on the indicator.

In an example embodiment of any of the above methods, processing the digital audio file is based on a user-defined profile.

In an example embodiment of any of the above methods, the method further comprises associating, by the processor, the plurality of digital audio files with their respective performance upon one or more digital consumption platforms.

In an example embodiment of any of the above methods, the method further comprises analyzing, by the processor, the plurality of digital audio files using machine learning.

Another example embodiment is a method which includes dividing, by a processor, a digital audio file into a plurality of blocks in a time sequence at 400 ms; determining, by the processor, a respective Loudness Units relative to Full Scale (LUFS) for each block; determining, by the processor, a difference between the LUFS of each block with a next block; and generating, by the processor, a real impact value (RIV) from one or more of the differences of the plurality of blocks within a second time length.

Another example embodiment is a method which includes dividing, by a processor, a digital audio file into a plurality of blocks in a time sequence at 50 ms; determining, by the processor, a respective Loudness Units relative to Full Scale (LUFS) for each block; determining, by the processor, a difference between the LUFS of each block with a next block; and generating, by the processor, a textural impact value (TIV) from one or more of the differences of the plurality block within a second time length.

Another example embodiment is a method which includes dividing, by a processor, a digital audio file into a plurality of blocks in a time sequence at 400 ms and each block having a 75% overlap with a previous block; determining, by the processor, a respective Loudness Units relative to Full Scale (LUFS) for each block; determining, by the processor, a difference between the LUFS of each block with a baseline value; and generating, by the processor, local organized clusters (LOCL) from one or more of the differences of the plurality block within a second time length.

Another example embodiment is a method which includes dividing, by a processor, a digital audio file into a plurality of blocks based on BPM of the audio file; determining, by the processor, a respective Loudness Units relative to Full Scale (LUFS) for each block; determining, by the processor, a difference between the LUFS of each block with a next block of the each block; and generating, by the processor, a BMP-based Impact Value (BIV) of the digital audio file from one or more of the differences of the plurality of blocks within a second time length.

Another example embodiment is a method which includes dividing, by a processor, a digital audio file into a plurality of windows in a time sequence at a first time length; dividing, by the processor, each of the plurality windows into a plurality of blocks in a time sequence at a second time length; determining, by the processor, a respective Loudness Units relative to Full Scale (LUFS) for each of the plurality blocks; determining, by the processor, a difference between the LUFS of each of the plurality blocks with a reference value; and generating, by the processor, a Linear Impact (LIV) value for each of the plurality of the windows.

Another example embodiment is a method which includes dividing, by a processor, a digital audio file into a plurality of windows in a time sequence at a first time length; dividing, by the processor, each of the plurality windows into a plurality of blocks in a time sequence at a second time length and each of the plurality blocks having a 75% overlap with a previous block; determining, by the processor, a respective Loudness Units relative to Full Scale (LUFS) for each of the plurality blocks; determining, by the processor, an average LUFS value of the plurality blocks within the each of the plurality of window; and generating, by the processor, a local organized clusters (LOCL) for each of the plurality of windows within the first time length based on the average LUFS value of the plurality of blocks for each of the plurality of the windows.

### BRIEF DESCRIPTION OF THE DRAWINGS

Reference will now be made, by way of example, to the accompanying drawings which show example embodiments, and in which:

FIG. 1 is an exemplary block diagram of a digital audio measurement system, according to an example embodiment;

FIG. 2A is a flow chart of a digital audio measurement method implemented by the digital audio measurement system of FIG. 1, according to an example embodiment;

FIG. 2B is a flow chart of an exemplary digital audio measurement method for generating real impact value (RIV) of an audio file, according to an example embodiment;

FIG. 2C is a flow chart of another exemplary digital audio measurement method for generating textural impact value (TIV) of an audio file, according to another example embodiment;

FIG. 2D is a flow chart of another exemplary digital audio measurement method for generating a BMP-based Impact Value (BIV) of an audio file, according to another example embodiment;

FIG. 2E is a flow chart of another exemplary digital audio measurement method for generating local organized clusters (LOCL) of an audio file, according to another example embodiment;

FIG. 3 is a timeline diagram illustrating division of an audio file, according to an example embodiment;

FIGS. 4A and 4B are charts illustrating examples of using real impact value (RIV) that indicates the differences between the two songs with regard to dynamics characteristics;

FIGS. 5A and 5B are charts illustrating examples of using textural impact value (TIV) that indicates the differences between two songs with regard to dynamics characteristics;

FIG. 6 is a timeline diagram illustrating division of an audio file, according to another example embodiment;

FIG. 7 is a chart illustrating an exemplary analysis of local organized clusters (LOCL);

FIG. 8 is another flow chart of another digital audio measurement method implemented by the digital audio measurement system of FIG. 1, according to another example embodiment; and

FIG. 9 is another flow chart of another digital audio measurement method implemented by the digital audio measurement system of FIG. 1, according to another example embodiment.

Similar reference numerals may have been used in different figures to denote similar components.

### DETAILED DESCRIPTION

In examples, time periods commonly associated with measurement of an audio file may include: Momentary (MT): 400 milliseconds; Short Term (ST): 3 seconds; Long Term (LT): 10 seconds; and Integrated: the entire duration of the audio data stream. MT and ST are commonly used for both blocks and measurement windows.

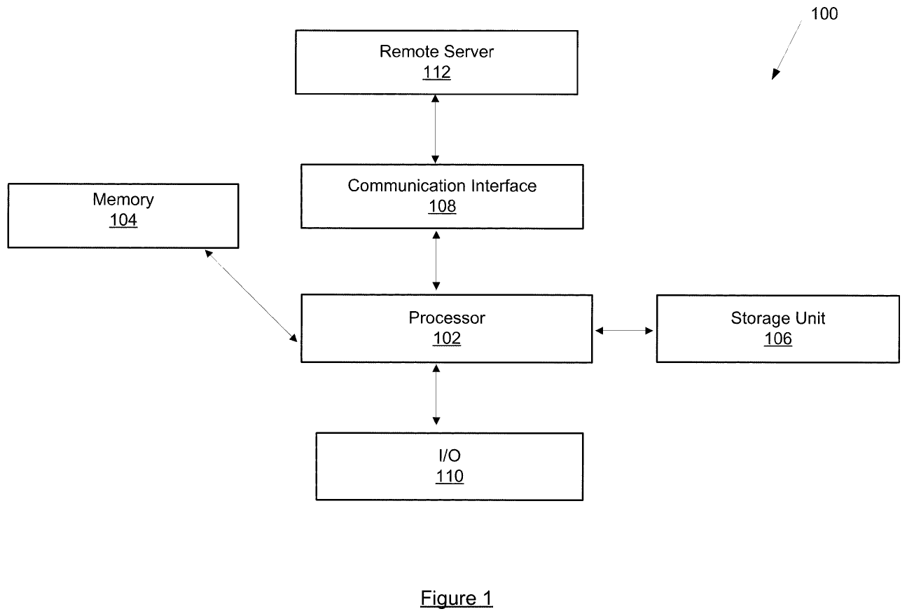

FIG. 1 illustrates an example embodiment of a digital audio measurement system 100 (also called system). The system 100 may include a digital audio device, a digital audio platform. The system 100 may be used for processing one or more digital audio files. A digital audio file includes MPEG-1 Audio Layer 3 (MP3), Waveform (WAV), Advanced Audio Coding (AAC), Windows Media Audio (FLAC), OGG, or Windows Media Audio (WMA), etc. The audio file may be in Pulse-Code Modulation (PCM) format with one or more channels. PCM is a common audio format used in CDs and DVDs. A digital audio file may be a music file.

In the example of FIG. 1, the system 100 includes a processor 102, one or more memories 104, one or more storage units 106, one or more communication interfaces 108, and one or more Input/Output (V/O) Interface 110. Although FIG. 1 shows a single instance of each component, there may be multiple instances of each component in the system 100.

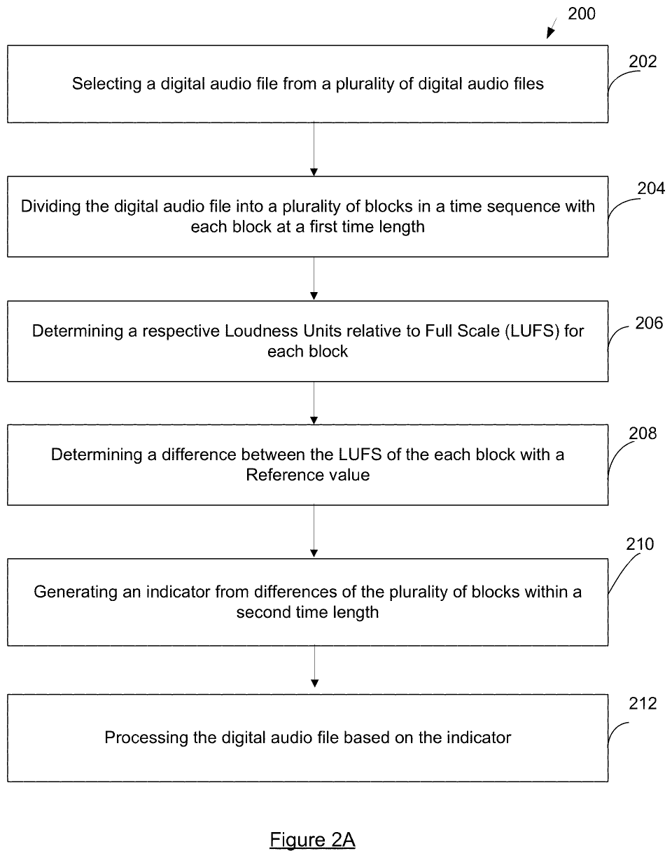

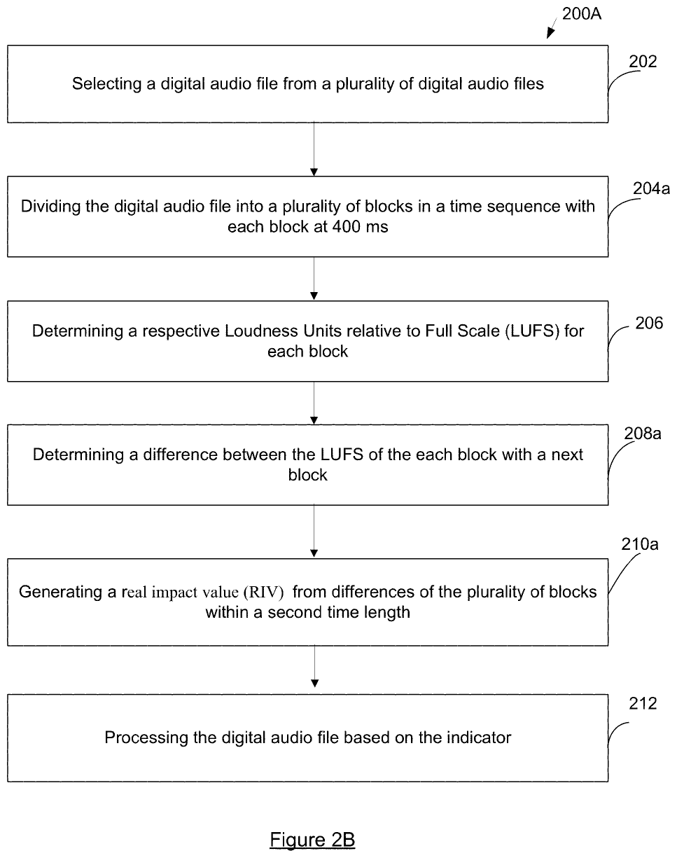

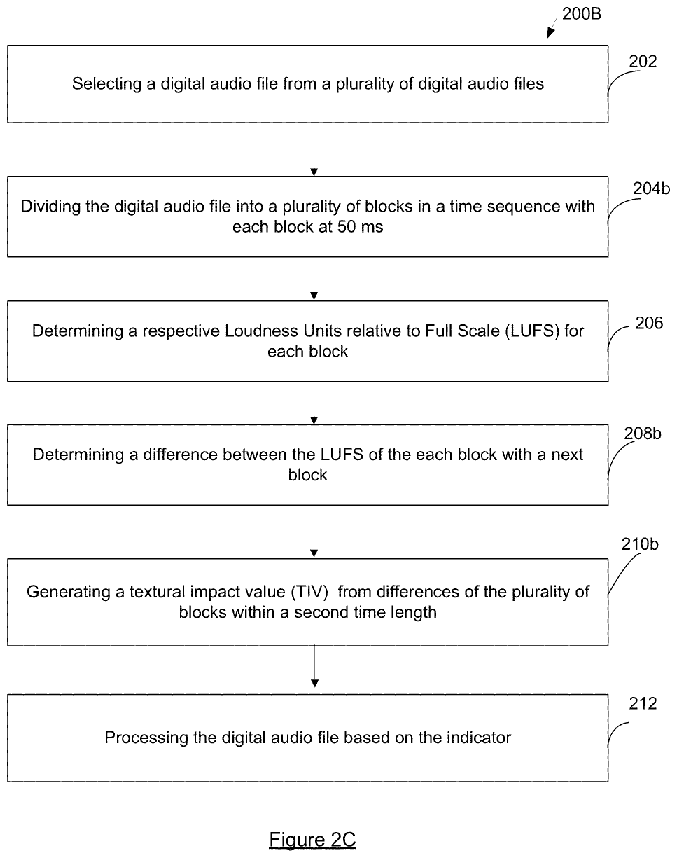

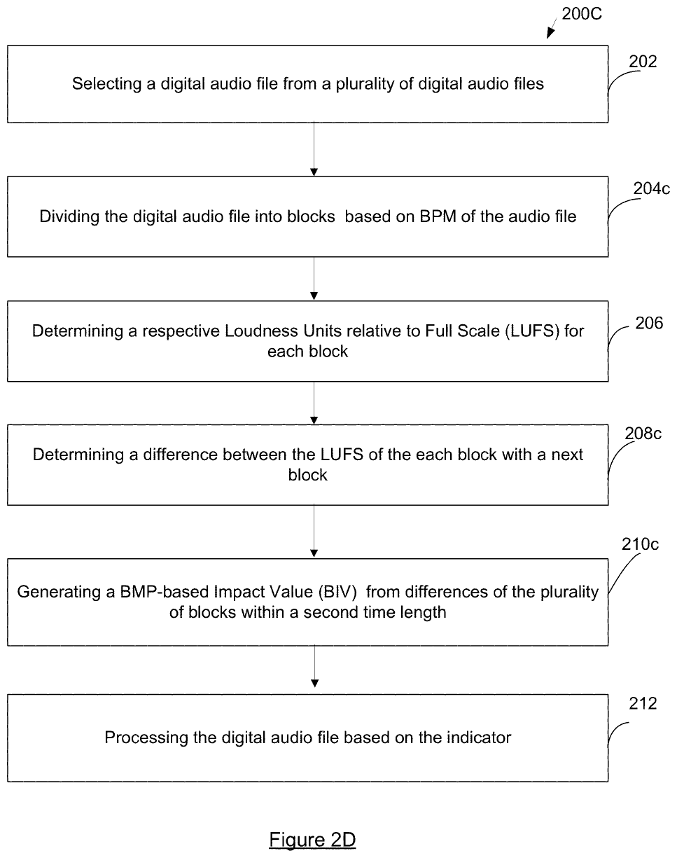

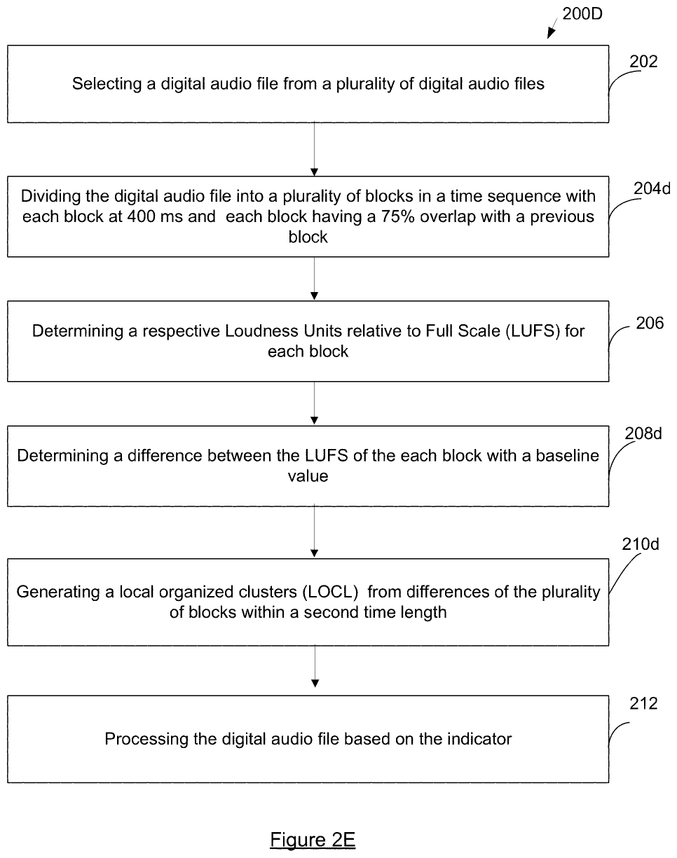

The processor 102 is configured to implement a digital audio measurement method 200 (also called method) to be described below in greater detail in relation to FIG. 2. The processor 102 may be a central processing unit (CPU), a microprocessor, an application-specific integrated circuit (ASIC), a field-programmable gate array (FPGA), dedicated logic circuitry, or combinations thereof.

The memory 104 is configured to store audio files, interim data for processing the audio file, instructions, codes, or statements, which when executed by the processor 102, caused the processor 102 to perform predetermine functions, such as the method 200. The memory 104 may include a volatile or non-volatile memory (e.g., a flash memory, a random access memory (RAM), and/or a read-only memory (ROM)). The non-transitory memory(ies) 104 may store instructions for execution by the processor 102, such as to carry out the example embodiments of the method. The memory(ies) 104 may include other software instructions, such as for implementing an operating system and other applications/functions. In some examples, one or more data sets and/or module(s) may be provided by an external memory (e.g., an external drive in wired or wireless communication with the system 100) or may be provided by a transitory or non-transitory computer or processor-readable medium. Examples of non-transitory computer readable media include a RAM, a ROM, an erasable programmable ROM (EPROM), an electrically erasable programmable ROM (EEPROM), a flash memory, a CD-ROM, or other portable memory storage.

The storage unit 106 is configured to store data for a relevant longer period. The storage unit 106 may include a mass storage unit such as a solid state drive, a hard disk drive, a magnetic disk drive and/or an optical disk drive.

In some examples, the system 100 may also include a communication unit 108 for a user to communicate with a remote server, such as a cloud server, via the communication unit 108. The remote server may store audio files.

A user may manually configure or control the system 100 via the I/O interface 110, such as a screen, a key board and/or a mouse. The I/O interface 110 may also output information generated from the system 100, for example on a display screen of the system 100.

The system 100 may be configured to implement the method 200 for processing one or more digital audio files. The method 200 may be a LIV.

In examples, Linear Impact Value (LIV) may be used to measure the differences between the loudness of sequential blocks of audio data. Depending on the time constant used, LIV can provide a broad range of microdynamic and macrodynamic insights within a linear timeline. LIV may include RIV, TIV, and BIV.

In method 200, the processor 102 is configured to process one or more digital audio files to improve audience experience in real time or as pre-processing, prior to outputting or further processing of the digital audio files.

As illustrated in FIG. 2, at step 202, the processor 102 is configured to select a digital audio file from a plurality of digital audio files. The plurality of audio files may be in a PCM format, and may be music files for compiling a playlist. The digital audio file may be an audio data stream. The audio files may have different channel modes and frequency bands.

In an example, the processor 102 may normalize the data of the selected digital audio file to floats between −1 and 1, excluding −1 and 1.

In an example, the processor 102 is configured to filter the digital audio file in one or more frequency bands.

In some examples, the indicator including LIV, RIV, TIV, LOCL, LOCL MT, and LOCL ST can apply to any or all of the following frequency bands:
“Low”—0-250 Hz
“Sub”—0-100 Hz
“Low Sub”—0-50 Hz
“Low-Mid” 250-500 Hz
“Wool” 100-250 Hz
“Mid”—250-2000 Hz
“Central Mid”—500-1500 Hz
“High Mid”—1500-4000 Hz
“Critical”—1500-5500 Hz
“High”—2000-5000 Hz
“Presence”—4000-7000 Hz
“Sibilance”—5000-12000 Hz
“Pointedness”—7000-12000 Hz
“Air”—12000 Hz-20000 Hz
“Ultrasonic”—20000 Hz-30000 Hz
“Consumer Domain”—80-15000 Hz
“Sad Consumer”—100-12000 Hz
“Full-Spectrum”—20-20000 Hz
“Full-Spectrum+Ultrasonic”—20-30000 Hz
“Ultrasonic Plus”—30000-1000000 Hz
“Megasonic”—1000000-10000000 Hz
Full Range (FR): unfiltered data or LUFS filter used
Subharmonic Density (SHD): sub-80 Hz (−3 dB at 80 Hz for lowpass)
Bass Density (BAS): 55-200 Hz (−3 dB at 55 Hz for lowpass, −3 dB at 200 Hz for highpass)
Midrange Density (MRD): 250-2 kHz (bandpass, −3 dB at 160 Hz and 3.15 kHz)
High-Frequency Density (HFD): 2 kHz-5 kHz (bandpass, −3 dB at 1.4 kHz and 6.85 kHz)
Sibilant Density or Sibilance (SBL): 5 kHz-12 kHz (bandpass, −3 dB at 3.6 kHz and 14.5 kHz).

The set of channel modes run when analyzing an audio file is determined by the number of channels in the audio file. In some examples, the indicator including LIV, RIV, TIV, LOCL, LOCL MT, and LOCL ST can apply to any or all of the following channel sets:
Mono: mono;
Stereo: left, right, mid, side, stereo; or
Surround (up to 7.1): left, right, center, Low-Frequency Effects (LFE) for 5.1 and 7.1 tracks, left surround, right surround, left side rear, right side rear, combined (all except LFE). The left side rear and right side rear channels are only used for 7.1 files.

At step 204, the processor 102 is configured to divide the audio file into a plurality of blocks in a time sequence with each block at a time length. The time length may be any user-desired time length, such as 400 ms, 3 seconds, and 10 seconds, or any time duration.

The time length of a block may also be referred to a block window. A block window is the smallest unit of time length of an audio file.

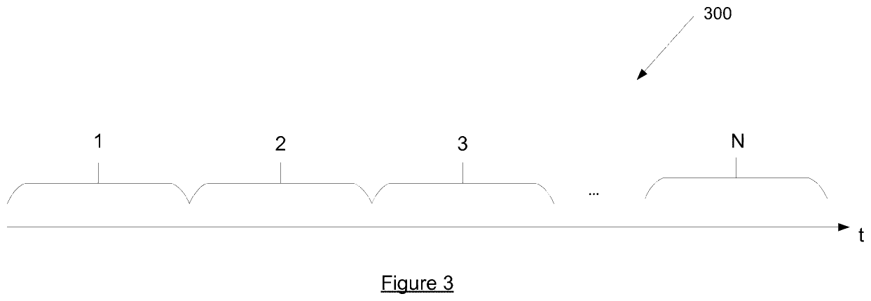

As illustrated in the example of FIG. 3, the processor 102 is configured to divide a digital audio file 300 into 1, 2, 3, . . . , N blocks in a time sequence. Each block may have a time length, such as 400 ms.

At step 206, the processor 102 is configured to determine a Loudness Unit relative to Full Scale (LUFS) for each block. LUFS is a standard loudness measurement unit used for audio normalization in broadcast television systems and other video and music streaming services. In the example of FIG. 3, the processor 102 is configured to measure a LUFS for each of blocks 1, 2, 3, . . . N. The processor 102 may store the LUFS in association with each block in an array in the memory 104. The LUFS for each block can be an ungated LUFS.

In some examples, if a LUFS value is −inf, which indicates that the LUFS is too quiet to measure. The processor 102 may set this LUFS value to the lowest measurable LUFS value of the entire digital audio file as −inf. For example, if the minimum LUFS block measurement is greater than −70, the −inf values can be set to −70.

At step 208, the processor 102 is configured to determine a difference between the LUFS of each block with a reference value. In the example of FIG. 3, the reference value is the LUFS of the next block of each block. The processor 102 is configured to compare a difference d1 in LUFS between block 1 and block 2, d2 in LUFS between block 2 and block 3, d3 in LUFS between block 3 and block 4, . . . , dn−1 in LUFS between block N−1 and block N. For example, d1, d2, d3, . . . dn−1 may be determined by subtracting the LUFS of a block from the LUFS of the next block.

At step 210, the processor 102 is configured to generate an indicator from differences of the plurality of blocks within a second time length. The indicator may indicate a relative perceived loudness level of the digital audio file in a period, or distribution of powers in a digital audio file. The indicator may be a mean value of differences in a period. In the example of FIG. 3, the processor 102 is configured to generate a mean value of differences among d1, d2, d3, . . . dn−1 of blocks 1, 2, 3, . . . N. in a period, or a measurement window. For example, the period may be the entire time period of the audio file, or a selected time period, such as differences of blocks in a 3-second period, in 10-second period. The processor 102 may determine the mean value using arithmetic mean value or geometric mean value. The mean value for a period is an average of the sequential differences of blocks at a time length, such as 400 ms, within a measurement window. In some example, the indicator is the linear impact value (LIV).

The second time length may also be referred to as a measurement window. The measurement window may be a sliding period of time which is greater than or equal to the first time length or block window.

In some examples, measurement of loudness may also involve a reporting window, which can be the total period of time of an audio file but can vary for real-time analysis. A reporting window is greater than or equal to the second time length.

The processor 102 may be configured to associate the indicator of digital audio file with one or more qualifiers. For example, a user can qualify passages of (or the entirety of) audio files with words, colors, adjectives, mood tags, or any combination of qualifiers that denote the user's perception of the audio file. A mood tags, or a user defined mood tag, is a classification of mood defined by a user to describe the emotion expressed in a song.

For example, a user can listen to a 30-second passage of an audio file while they are prompted to qualify the audio passage in real time. The user may qualify the passage as “somber” and “quiet”. These qualifiers would be correlated with indicator of the same audio file or passage. The qualifiers and the correlation can be stored and linked to the user's profile. After a sufficient number of passages or entire audio files have been qualified by the user, a “Schema” can be created for that specific user's perception of audio based on the ranges within which qualifiers typically fall.

At step 212, based on the indicator, the processor 102 is configured to further process the digital audio file based on the indicator. For example, the processor 102 may sequence or group the audio file based on the indicator for playback among the plurality of the audio files. The audio file may then be rendered in a user device or a platform in a selected sequence or in a selected group. In some examples, based on the indicator or the mean value, the processor 102 may compile or adjust the digital audio file for playback among the plurality of the audio files.

In some examples, the processor 102 can process the digital audio file includes: amplification, attenuation, compression, equalization, normalization, expansion, limiting, envelope filtering, transient suppression, transient enhancement, and frequency-based dynamics processing such as high-frequency limiting or high-frequency expansion, multiband compression or expansion.

In some examples, the processor 102 is configured to output the indicator to a user interface, such as a display screen. In some examples, the processor 102 is configured to associate the indicator with the audio file or a segment of the audio file, and store the association in memory 104 or database.

In some examples, the processor 102 may output or visualize the indicator or the mean value, and/or perform further statistical computations, for the short, long and/or integrated measurement window. For example, the processor 102 may create a distribution of short-term Real Impact Value (RIV), Textural Impact Value (TIV), and Local Organized Clusters (LOCL) of the digital audio file.

Because method 200 operates based on linear differences, the processor 102 can measure dynamics of the digital audio file accurately and reliably. Method 200 allows to accurately measure the perceived volume of reference sources by the audience. Music producers and streaming normalization systems can use method 200 to optimize the sequence of audio files on a playlist to improve the experience of the audience. Each digital audio file on a playlist can play back at a user-defined level when played on digital streaming platforms.

The method 200 may be used to determine real impact value (RIV), textural impact value (TIV), and local organized clusters (LOCL) of the audio file.

RIV is used to indicate moment-to-moment relative perceived impact in a digital audio file, indicating microdynamic fluctuations within a linear timeline. Perceived Impact refers to the relative amount of momentary dynamic variance within an audio source, such as a digital audio file, and may be indicated by RIV, TIV or LOCL. Momentary time constants in blocks of the digital audio file are compared against each other in succession in order to measure the range of microdynamic fluctuation on a linear timeline.

Referring to FIG. 2B, method 200A is an example embodiment of method 200 for generating a RIV of a digital audio file. To generate the RIV of a digital audio file using method 200A, after the processor 102 selects or receives a digital audio file at step 202, the processor 102 may normalize the data of the selected digital audio file to floats between −1 and 1 (not including those values).

In method 200A, the processor 102 performs step 202 as described in method 200 above.

At step 204a, the processor 102 divides the digital audio file into a plurality of blocks with each block at a time length of 400 ms. The processor 102 ignores the last block if it is shorter than 400 ms, or an incomplete block.

The processor 102 proceeds to perform step 206 as described in method 200 above.

At step 208a, the processor 102 is configured to determine a difference between the LUFS of each block with a next block. In the example of FIG. 3, the processor 102 is configured to compare a difference d1 in LUFS between block 1 and block 2, d2 in LUFS between block 2 and block 3, d3 in LUFS between block 3 and block 4, . . . , dn−1 in LUFS between block N−1 and block N. For example, d1, d2, d3, . . . dn−1 may be determined by subtracting the LUFS of a block from the LUFS of the next block.

At step 210a, the processor 102 is configured to generate a real impact value. Therefore, in method 200a, the indicator is the RIV value of the digital audio file. RIV may be generated for blocks in a second period or a time length of the digital audio file. For example, the period may be a short term of 3 seconds, a long term of 10 seconds, or integrated for an entire duration of the digital audio file.

The processor 102 proceeds to perform step 212 as described in method 200 above.

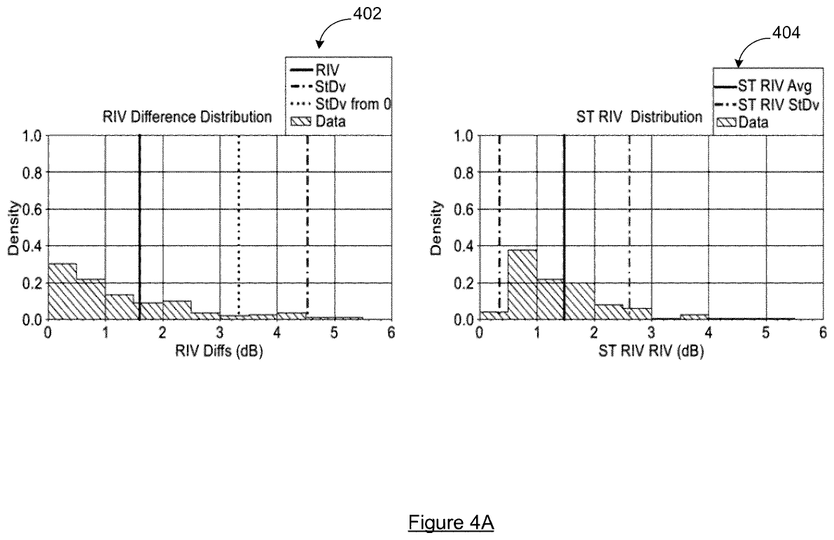

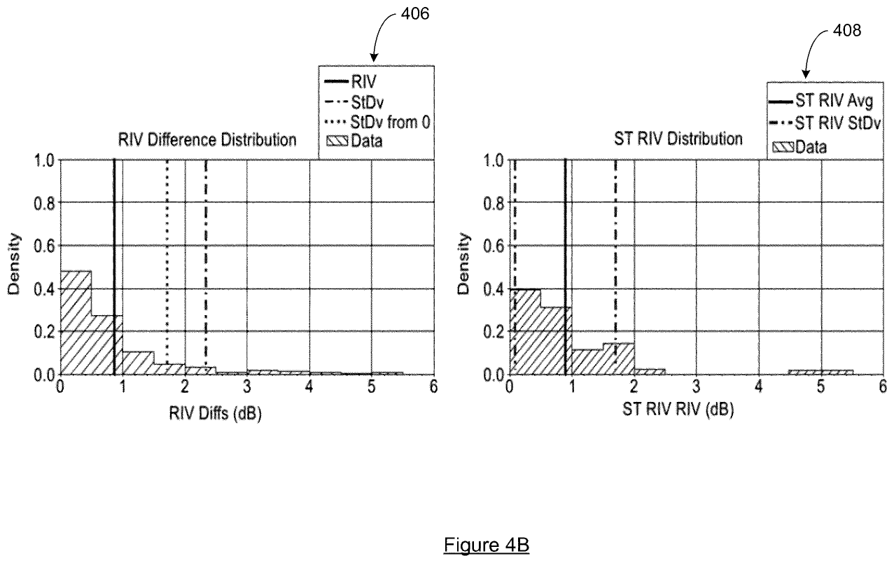

FIGS. 4A and 4B illustrate examples of using RIV that indicate the differences between the two songs with regard to their dynamics characteristics. These differences are disregarded by conventional loudness measurement schemes. In FIG. 4A, diagram 402 illustrates a distribution of serial differences in decibels recorded for the duration of the song Pity Party. Diagram 404 illustrates a distribution of recorded Short Term Real Impact Values for the duration of the song. In FIG. 4B, diagram 406 illustrates a distribution of serial differences in decibels recorded for the duration of the song Stretch Marks. Diagram 408 illustrates a distribution of recorded Short Term Real Impact Values for the duration of the song. Both songs have been LUFS matched to −16.0 and are 24-bit 44.1 kHz .wav files.

The song in FIG. 4B has an Integrated RIV of 2.863 with an average Short Term RIV of 3.04, and a ST RIV of 2.931. Compared to the song in FIG. 4A, which reports an Integrated RIV of 1.611, an average Short Term RIV of 1.55, and a ST RIV of 2.931. The song in FIG. 4B sounds more perceptibly impactful, and therefore louder than the song in FIG. 4A when it is played back at the same LUFS.

In order to compensate for the difference in perceived impact, a music producer can increase or decrease the amount of perceived impact in one or both tracks to achieve optimal playback. For example, the comparably more compressed song track Pity Party can be remastered with less compression and saturation to allow for more momentary dynamic variance, resulting in a higher perceptible impact and therefore a higher Real Impact Value. Conversely, the more dynamic track, Stretch Marks can be remastered with more peak compression, resulting in lower perceived impact and a lower Real Impact Value.

TIV can be used to indicate the relative perceived microdynamic or textural impact of a digital audio file, and to indicate microdynamic fluctuations within a linear timeline. TIV is a key indicator for perceived loudness based on the amount of microdynamic or textural impact perceived from the audio passage. Perceived Textural Impact refers to the relative amount of microdynamic variance within an audio source, such as a digital audio file. Compared with RIV, in TIV, relatively short time constants in the digital audio file are compared against each other in succession in order to indicate the range of microdynamic fluctuation on a linear timeline. Textural Impact Value of a digital audio file is the average difference between blocks within a specified window of time.

Referring to FIG. 2C, method 200B is another example embodiment of method 200 for generating a TIV. To generate the TIV of a digital audio file using method 200B, after the processor 102 selects or receives a digital audio file at step 202 as described in method 200 above, the processor 102 may normalize the data of the selected digital audio file to floats between −1 and 1, excluding −1 and 1.

At step 204b, the processor 102 divides the digital audio file into a plurality of blocks with each block at a time length of 50 ms. The processor 102 ignores the last block if it is shorter than 50 ms, or is an incomplete block.

The processor 102 proceeds to perform step 206 as described in method 200 above.

At step 208b, the processor 102 is configured to determine a difference between the LUFS of each block with a next block. As illustrated in the example of FIG. 3, the processor 102 is configured to compare a difference d1 in LUFS between block 1 and block 2, d2 in LUFS between block 2 and block 3, d3 in LUFS between block 3 and block 4, . . . , dn−1 in LUFS between block N−1 and block N. For example, d1, d2, d3, . . . dn−1 may be determined by subtracting the LUFS of a block from the LUFS of the next block.

At step 210b, the indicator is a textural impact value (TIV) of the digital audio file. TIV may be generated for blocks in a period or a second time length of the digital audio file. For example, the period or measurement window can be a measurement window of a momentary of 400 ms, a short term of 3 seconds, a long term of 10 seconds, or integrated for an entire duration of the digital audio file. The TIV for a measurement window is defined as the average of the sequential differences of the 50 ms blocks within a measurement window.

The processor 102 proceeds to perform step 212 as described in method 200 above.

Because TIV operates on a serial difference measurement scheme with extremely short windows, accurate and reliable textural impact measurements can be recorded with method 200.

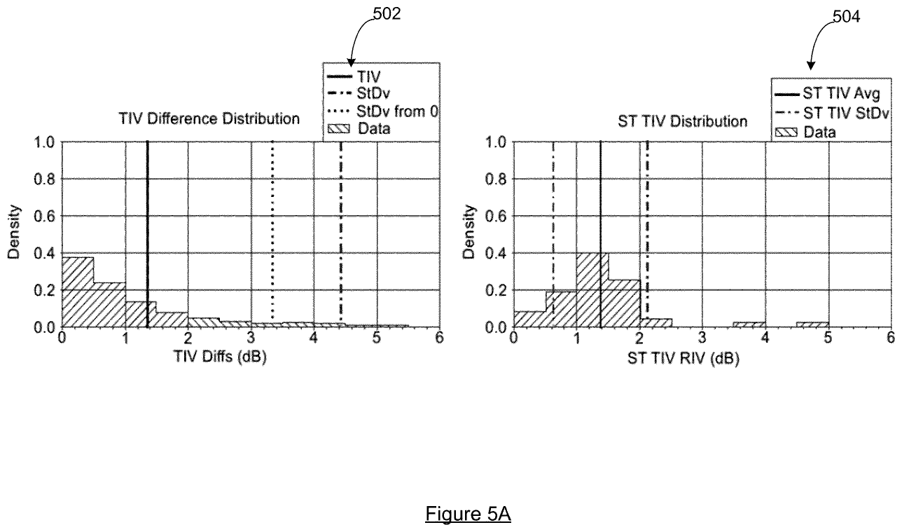

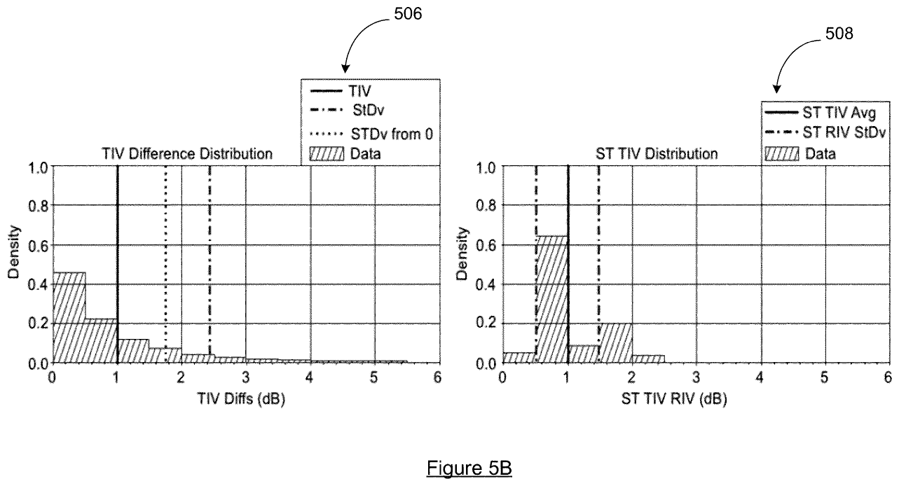

FIGS. 5A and 5B illustrate examples of using TIV that indicate the differences between the two songs with regard to their dynamics characteristics. These differences are disregarded by conventional loudness measurement schemes. In FIG. 5A, diagram 502 illustrates a distribution of serial differences in decibels recorded for the duration of the song Sanjuan Renfrew. Diagram 504 illustrates a distribution of recorded Short Term Textural Impact Values for the duration of the song. In FIG. 5B, diagram 506 illustrates a distribution of serial differences in decibels recorded for the duration of the song IDOL. Diagram 508 illustrates a distribution of recorded Short Term Textural Impact Values for the duration of the song. Both songs are 24-bit 44.1 kHz wav files.

Sanjuan Renfrew in the example of FIG. 5A has an Integrated LUFS of −6.1, which should be perceived as being louder than IDOL in the example in FIG. 5B, a song with a much lower Integrated LUFS of −9.8. However, due to the amount of microdynamic impact perceived from IDOL in FIG. 5B, IDOL is perceived as being significantly louder than Sanjuan Renfrew.

IDOL in FIG. 5B has an Integrated LUFS of −9.802, TIV of 2.779, ST TIV of 2.797, and a Mean of 2.18. Sanjuan Renfrew in FIG. 5A has an Integrated LUFS of −6.151, TIV of 1.00, ST TIV of 0.992, and a Mean of 0.61.

The TIVs in FIGS. 5A and 5B indicate the textural and microdynamic differences between the two songs, allowing streaming platforms, broadcasters, film and TV professionals, and music producers to accurately measure and predict the amount of perceived textural and microdynamic impact that comes from a digital audio file.

TIV may be used in applications involving measuring the textural impact or microdynamic qualities of audio passages. For example, a film trailer producer may be searching for songs that maintain a high level of textural impact in order to demand attention from the audience from the beginning of the trailer. By referring to TIVs rather than LUFS, a curated library of songs that fall within the predetermined textural parameters of the producer can be created in real-time. Using this library, the producer is able to save time and energy by only auditioning songs that are likely to fit the project's needs.

BPM-based Impact Value (BIV) uses the tempos of an audio file to set the block size used by LIV. Various subdivisions of notes are used to provide a broad range of beat-based insights, from macrodynamic measure-to-measure data to 64th note-based microdynamics. Table 1 below is an example of BIV of an exemplary song “Carnivorous Plant”. Table 1 includes both the window sizes and measurements for the example song.

TABLE 1
CARNIVOROUS PLANT - Linear Impact Value (LIV) Stereo Full Range (FR)

| | | | | | STD DEV | MEDIAN | | |
|---|---|---|---|---|---|---|---|---|
| | | | T | STD | FROM | ABSOLUTE | | |
| MEAN | MEDIAN | MODE | RANGE | DEV | 0.0 | DEVIATION | BLOCK | NOTE |
| (dBFS) | (dBFS) | (dBFS) | (dBFS) | (dBFS) | (dBFS) | (dBFS) | SIZE (s) | DENOM |
| 0.68 | 0.35 | 0.1 | 1.50 | 0.85 | 1.09 | 0.23 | 1.95 | Whole |
| 2.50 | 1.10 | 0.6 | 5.86 | 5.51 | 6.05 | 0.66 | 0.98 | half |
| 1.88 | 0.80 | 0.4 | 3.89 | 4.01 | 4.43 | 0.54 | 0.49 | quarter |
| 2.58 | 1.30 | 0.3 | 4.62 | 5.49 | 6.06 | 0.89 | 0.24 | eighth |
| 2.25 | 1.09 | 0.3 | 4.64 | 4.64 | 5.16 | 0.76 | 0.12 | 16th |
| 2.20 | 0.95 | 0.2 | 5.23 | 4.15 | 4.70 | 0.73 | 0.06 | 32nd |
| 1.56 | 0.72 | 0.2 | 3.48 | 2.96 | 3.35 | 0.53 | 0.03 | 64th |

Referring to FIG. 2D, method 200C is another example embodiment of method 200 for generating a BIV. To generate the BIV of a digital audio file using method 200C, after the processor 102 selects or receives a digital audio file at step 202 as described in method 200 above, the processor 102 may normalize the data of the selected digital audio file to floats between −1 and 1, excluding −1 and 1.

At step 204c, the processor 102 divides the digital audio file into a plurality of blocks based on BPM of the audio file. The block size may include the whole, half, quarter, 8th, 16th, 32nd, and 64th note-sized blocks, or any other note-size used in the audio file.

The processor 102 proceeds to perform step 206 as described in method 200 above.

At step 208c, the processor 102 is configured to determine a difference between the LUFS of each block with a next block. As illustrated in the example of FIG. 3, the processor 102 is configured to compare a difference d1 in LUFS between block 1 and block 2, d2 in LUFS between block 2 and block 3, d3 in LUFS between block 3 and block 4, . . . dn−1 in LUFS between block N−1 and block N. For example, d1, d2, d3, . . . dn−1 may be determined by subtracting the LUFS of a block from the LUFS of the next block.

At step 210c, the indicator is a BMP-based Impact Value (BIV) of the digital audio file.

The processor 102 proceeds to perform step 212 as described in method 200 above.

LOCL indicates loudness, the level of compression and/or dynamics of a digital audio file. LOCL also provides information on the macrodynamic nature of a digital audio file regarding relative loudness of the digital audio file in a selected period.

In addition, if LOCL is applied to various frequency bands that are indicative of key audio characteristics like subharmonic density, high-frequency density, and sibilance, LOCL can be used to achieve far-reaching capabilities with regard to audio qualification, categorization, compilation, and sequencing.

LOCL can be applied to PCM data of a digital audio file in order to indicate and report the distribution of powers in a digital audio file. LOCL determines the LUFS of a digital audio file before deriving an average difference between the measured “baseline” LUFS of the audio file and all other measured sum-of-powers momentary LUFS above and below the baseline LUFS. In some examples, “baseline” can be a user-defined reference value. In some examples, the “baseline” can be a Mean Short Term LUFS. LUFS is a synonym for Loudness, K-weighted, relative to full scale (LKFS). LKFS is a standard loudness measurement unit used for audio normalization in broadcast television systems and other video and music streaming services. LKFS is standardized in ITU-R BS.1770.

In some examples, LOCL can be applied to individual frequency bands for frequency-based dynamics analysis. For example, by applying various spectral filters to the audio data, LOCL can be used to measure frequency-based dynamics that indicate tonal dynamics characteristics for an audio passage. Frequency-based dynamics can indicate the amount of bass included in the audio passage, or whether the bass is compressed or dynamic.

Referring to FIG. 2E, method 200D is another example embodiment of method 200 for generating LOCL of a digital audio file. To generate the LOCL of a digital audio file using method 200C, after the processor 102 selects or receives a digital audio file at step 202 as described in method 200, the processor 102 may normalize the data of the selected digital audio file to floats between −1 and 1, excluding −1 and 1.

In the example of generating a LOCL, processor 102 selects or receives a digital audio file at step 202, the digital audio file may be a WAV file containing PCM audio data with one or more channels. The processor 102 may normalize the data of the selected digital audio file to floats between −1 and 1, excluding −1 and 1.

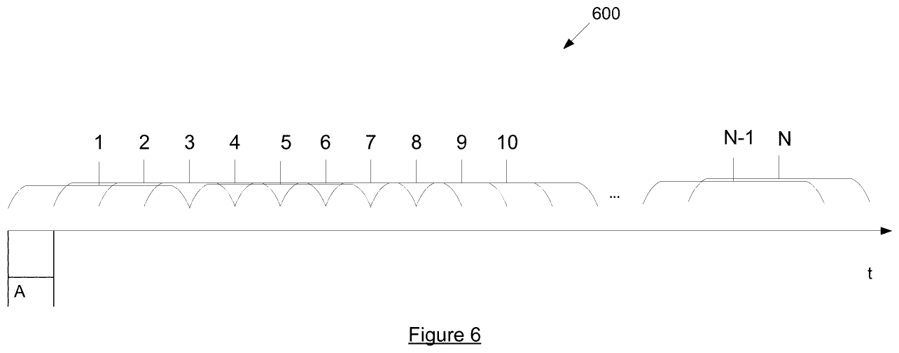

In the example of LOCL, at step 204d, the processor 102 divides the digital audio file into a plurality of blocks with each block at a fourth time length, such as 400 ms, with each block having an overlap, such as 75% overlap, with the previous block. As illustrated in the example of FIG. 6, the processor 102 is configured to divide a digital audio file 600 into 1, 2, 3, . . . , N blocks in a time sequence. Each block overlaps with the one or more of the subsequent blocks at the fourth time length. In the example of FIG. 6, each block 1 . . . N is 400 ms. Block 1 overlaps with subsequent blocks 2, 3, and 4 for example, for a quarter of the time length of block 1, and the length of portion A is about 75% of block 1. In the example of FIG. 6, at every 100 ms, a new block is created. The processor 102 may ignore the last block if it is shorter than 400 ms, or is an incomplete block.

Within each measurement window, at step 206 as described in method 200, the processor 102 is configured to determine a LUFS for each block within the measurement window. The measurement window may be 3 seconds, 10 seconds, or the entire duration of the audio data stream.

At step 206, the processor 102 may be further configured to iterate through the data stream in 400 ms blocks, for example by using lookahead function, and to measure a gated LUFS for each block. A gated LUFS is a LUFS measurement using the default gating scheme, as defined in ITU-R BS.1770. A LUFS pauses the measuring when the audio level drops below a threshold, such as −10 LU. An ungated LUFS is a modified LUFS measurement that ignores the two-part gating scheme, mainly used for LIV. In some implementations, ungated LUFS measurements can be capped at −90 dB LUFS, to avoid LUFS measurements below −90 dB being reported as silence.

The processor 102 is configured to repeat this process until all the blocks are processed.

Before step 208d, the processor 102 is configured to determine a baseline value. In the example of LOCL, the baseline value is defined as the average short-term LUFS for the PCM audio data.

The processor 102 may determine the baseline by looping through the PCM audio data in blocks with a third time length, such as 3 seconds, with a new block being started every second time length, such as 750 ms. In particular, the processor 102 is configured to measure a gated LUFS for each block, and to ignore incomplete blocks at the end of the track. Once the processor 102 has measured the LUFS of all the blocks, the processor 102 is configured to average all the LUFS values for the blocks. The average of all the LUFS values is the baseline for the digital audio file.

At step 208d, the processor 102 may then compare the LUFS of each block to the baseline and determine a difference between the LUFS of each block and the LUFS of the baseline. If the method 200 is used real-time, the baseline of the digital audio file is precomputed.

For example, after the processor 102 completes measuring the gated LUFS for each block, the processor 102 may divide all the 400 ms block LUFS values that are greater or equal to the baseline from those that are lower than the baseline. The processor 102 is configured to separately generate a first average of the difference between the baseline and LUFS values greater than the baseline, and a second average of the difference between the baseline and the LUFS values lower than the baseline. The first average and the second average are therefore absolute values to indicate average LUFS greater or lower than the baseline.

At step 210d, the indicator is generated with local organized clusters (LOCL) values of the digital audio file represented by the first and second average values. The LOCL value is the difference of the first and second average values. At step 210d, the processor 102 is configured to generate an indicator that may be a LOCL Value and LOCL analysis (computations). LOCL Value is the average of the differences between LUFS value of each block and the baseline LUFS value is calculated to obtain the LOCL value for the measurement window. LOCL value represents the amount of general dynamic variance for the measurement window, and is determined separately for the block LUFS values above the baseline and those below the baseline. LOCL analysis may include one or more of, within the second time length: a Standard Deviation of LUFS, measures of average LUFS, a comparative analysis of LUFS, or a distribution analysis of LUFS. The LOCL analysis can be output to another device or a display screen as figures or charts in real-time.

The processor 102 proceeds to perform step 212 as described in method 200 above.

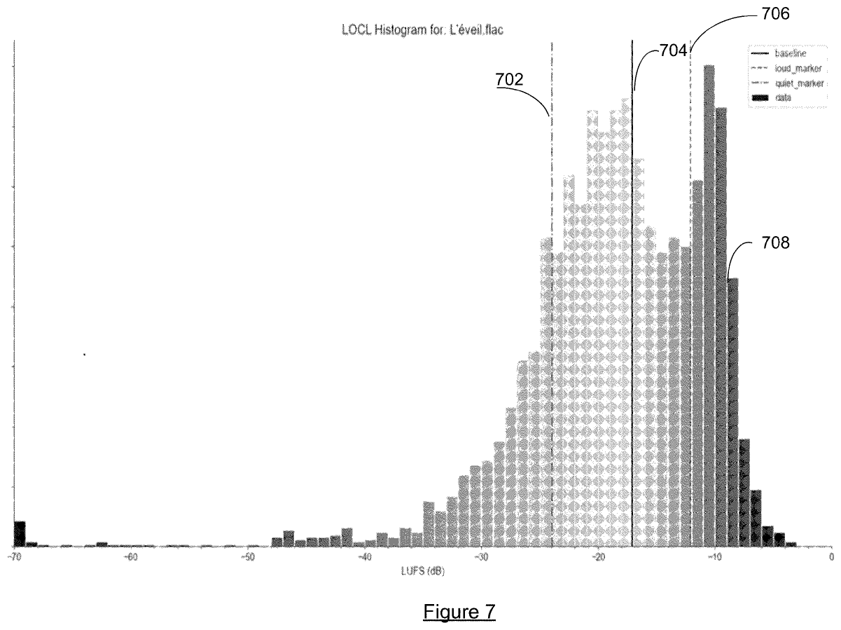

FIG. 7 is a diagram illustrating an exemplary analysis of LOCL. Line 702 indicate a second average of differences of quiet sound, which is less than the baseline LUFS 704. Loud blocks are defined as blocks with LUFS values above the baseline, while quiet blocks are defined as blocks with LUFS values below the baseline. The loud and quiet blocks' average difference from the baseline determines their respective loud and quiet markers. Line 706 indicates the first average of differences of loud sound which is greater than the baseline LUFS 704 of the LUFS data 708. FIG. 7 illustrates an example of distribution of momentary gated LUFS.

In some examples, the processor 102 is configured to determine any or all of:
Array of all recorded LUFS block measurements
Mean LUFS
Median LUFS
Mode LUFS
Standard Deviation
Maximum LUFS
Loud LUFS Marker
Quiet LUFS Marker
Range of Loud LUFS Marker to Quiet LUFS Marker
Marker Differences:
   Loud LUFS Marker to Mean Momentary LUFS
   Quiet LUFS Marker to Mean Momentary LUFS
   Loud LUFS Marker to Median Momentary LUFS
   Quiet LUFS Marker to Median Momentary LUFS
   Loud LUFS Marker to Mode Momentary LUFS
   Quiet LUFS Marker to Mode Momentary LUFS
   Loud LUFS Marker to Short Term Mean LUFS
   Quiet LUFS Marker to Short Term Mean LUFS
   Loud LUFS Marker to Short Term Median LUFS
   Quiet LUFS Marker to Short Term Median LUFS
   Loud LUFS Marker to Short Term Mode LUFS
   Quiet LUFS Marker to Short Term Mode LUFS
   Loud LUFS Marker to Long Term Mean LUFS
   Quiet LUFS Marker to Long Term Mean LUFS
   Loud LUFS Marker to Long Term Median LUFS
   Quiet LUFS Marker to Long Term Median LUFS
   Loud LUFS Marker to Long Term Mode LUFS
   Quiet LUFS Marker to Long Term Mode LUFS.

In some examples, the processor 102 may further determine mean, median, mode, Array of sequential differences, Array of ST RIV values, Standard Deviation, Standard Deviation from 0, Mean ST RIV, Median ST RIV, Mode ST RIV, ST RIV Standard Deviation, and/or other statistical measures of the digital audio file based on the 400 ms block LUFS values.

In an exemplary application of creating playlists for exercise sessions, an AI playlist curator can employ LOCL to sequence a selection of songs that rise and fall with the relative energy of the workout. The relative energy of the workout can be the user's heart rate, as measured by a user device connected to the user, such as a smart watch. Because LOCL of the songs can run on the cloud with lookahead, the user's measured heart rate can be used as an indicator of how much energy the next audio passage should convey. For example, the method can include receiving heart rate information from a heart rate detector and selecting one or more audio files in dependence of the heart rate information.

Furthermore, because LOCL is capable of analyzing a song's macrodynamic profile, high energy songs with dips or lulls in energy at various points can be omitted from the playlist entirely, which adds more cohesiveness to the playlist as a whole.

With the LOCL, users, being able to tweak parameters, can also “dial in” specific characteristics that they would like to prioritize, minimize, or omit entirely. For example, if a user is sensitive to high frequencies, LOCL can be used to identify and omit audio passages with excessive high-frequency density or sibilance. On the other hand, if a user prefers earth-shaking bass, LOCL can be used to identify and compile songs with a specific bass density.

Because LOCL can also run via pre-processing, playlists can be compiled specifically for high intensity interval training, where low energy songs mean low intensity rests and high energy songs mean high intensity sprints. For the consumers, this means a better workout where one can pay attention to the relative energy of the music rather than constantly peeking at a stopwatch. For the streaming company, it means greater customer engagement, satisfaction, and retention.

In some examples, the second time length at step 210d may vary. LOCL may include LOCL MT and LOCL ST. LOCL MT measures the distribution of momentary LUFS readings within the second time length of 400 ms. LOCL MT provides a user a bird's eye view of momentary loudness of the audio file. LOCL ST measures the distribution of momentary LUFS readings within the second time length of 3 s. LOCL ST is similar to LOCL MT, but with a more macrodynamic skew. In LOCL MT, momentary LUFS readings are used. In LOCL ST, Short-term LUFS readings are used. As well, LOCL ST is used for determining the baseline LUFS used by both LOCL MT and ST for the audio file.

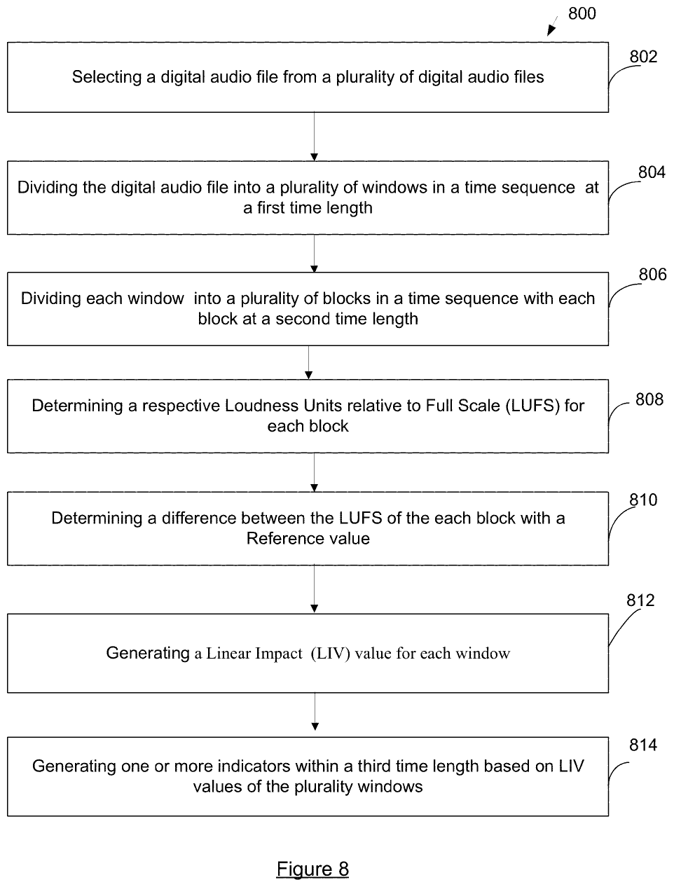

In some examples, the processor 102 is configured to implement a digital audio measurement method 800 illustrated in the flow chart of FIG. 8.

In method 800, the processor 102 is configured to measure the distribution of LIV values of an audio file across a given measurement window. LIV values may be determined using the audio file data in each window, and may be then used to calculate measures of an average LIV value and other values. Method 800 serves to average LIV, and allows for short-term to long-term analysis, depending on the window size.

As illustrated in FIG. 8, at step 802, the processor 102 is configured to select a digital audio file from a plurality of digital audio files. The plurality of audio files may be in a PCM format, and may be music files for compiling a playlist. The digital audio file may be an audio data stream. The audio files may have different channel modes and frequency bands as described in methods 200-200D above.

At step 804, the processor 102 is configured to divide the audio file into a plurality of windows in a time sequence with each window at a first time length. The first time length may be any user-desired time length, such as 3 seconds or any time duration.

At step 806, with respect to each window of the plurality of windows, the processor 102 is configured to divide each window into a plurality of blocks in a time sequence with each block at a second time length. The second time length may be any user-desired time length, such as 400 ms, or any time duration less than the first time length.

At step 808, the processor 102 is configured to determine a Loudness Unit relative to Full Scale (LUFS) for each block. The LUFS for each block can be an ungated LUFS.

At step 810, the processor 102 is configured to determine a difference between the LUFS of each block with a reference value. The reference value may be the LUFS of the next block of each block as illustrated in the example of FIG. 3 and described above. The processor 102 is configured to compare a difference d1 in LUFS between block 1 and block 2, d2 in LUFS between block 2 and block 3, d3 in LUFS between block 3 and block 4, . . . , dn−1 in LUFS between block N−1 and block N. For example, d1, d2, d3, . . . dn−1 may be determined by subtracting the LUFS of a block from the LUFS of the next block.

At step 812, the processor 102 is configured to average the differences between the per-block LUFS within each window for all of the plurality of windows, and generate a LIV value for each window. The LIV value may be generated in the same manner as described above in FIGS. 2A-2C.

At step 814, the processor 102 is configured to generate one or more indicators within a third time length based on the LIV values of the respective plurality of windows. The third time window may be the reporting window in this instance. The one or more indicators may be the Windowed Linear Impact (WLI) values. The third time length may be a sliding period of time which is greater than or equal to the first time length. The third time length may also be referred to as a measurement or reporting window. Other measurements are also derived from the LIV values for each window. For example, the other measurements may include the metrics for the windowed algorithms, such as WLI and WCL, that may be derived from the averaged values in each window, as opposed to the raw values from the blocks. The measurements are mostly the same as the non-windowed versions of those algorithms (mean, median, mode, standard deviation, MAD, T range, etc).

Table 2 is an example of WLI of a song “Carnivorous Plant”:

TABLE 2
CARNIVOROUS PLANT - Windowed Linear Impact Value (WLI) Stereo Full Range (FR)

| | | | | | MEDIAN | | | |
|---|---|---|---|---|---|---|---|---|
| | | | T | STD | ABSOLUTE | | | |
| MEAN | MEDIAN | MODE | RANGE | DEV | DEVIATION | BLOCK | WINDOW | NOTE |
| (dBFS) | (dBFS) | (dBFS) | (dBFS) | (dBFS) | (dBFS) | SIZE (s) | SIZE (s) | DENOM |
| N/A | N/A | N/A | N/A | N/A | N/A | 1.95 | 3 | whole |
| 1.95 | 0.75 | 0.3 | 4.09 | 4.83 | 0.47 | 0.98 | 3 | half |
| 2.72 | 0.99 | 0.7 | 5.73 | 5.48 | 0.42 | 0.49 | 3 | quarter |
| 2.67 | 1.64 | 1 | 6.45 | 3.15 | 0.76 | 0.24 | 3 | eighth |
| 2.51 | 2.01 | 1.6 | 3.62 | 1.86 | 0.62 | 0.12 | 3 | 16th |
| 2.24 | 1.86 | 1.6 | 3.26 | 1.21 | 0.48 | 0.06 | 3 | 32nd |
| 1.57 | 1.33 | 1.3 | 1.69 | 0.68 | 0.36 | 0.03 | 3 | 64th |

Table 2 includes both the window sizes and measurements for the example song.

The measurements for whole note WLI are shown as N/A because there are not enough blocks in a window: The block size is 1.95 seconds, while the window size is 3 seconds.

In some examples, Windowed Linear Impact (WLI) values may include Windowed Real Impact (WRI) values, Windowed BPM-based Impact (WBI) values, or Windowed BPM-based Impact (WBI) values.

WRI essentially is an averaged version of RIV, with an emphasis on analyzing short-term to short-term macrodynamic variance of RIV as described in FIG. 2B above. WRI provide a different perspective on the ‘average’ RIV across the reporting window.

WTI essentially is an averaged version of TIV, with an emphasis on analyzing short-term to short-term macrodynamic variance of TIV as described in FIG. 2C above. WTI offers a different perspective on the average TIV across the reporting window.

In the example of WRI and WTI, in method 800, each window at a first time length is 3 s, and block has a second time length of 400 ms.

WBI utilizes the tempo of the audio file to set the block size used by WLI, and the block size is then used to break up the standard 3-second windows. [Various subdivisions of notes are utilized to provide a broad range of beat-based insights for short-term windows.

In the example of WBI, in method 800, each window at a first time length is 3 s, and each block has a second time length based on BPM. The second time length may be whole, half, quarter, 8th, 16th, 32nd, and 64th note-sized.

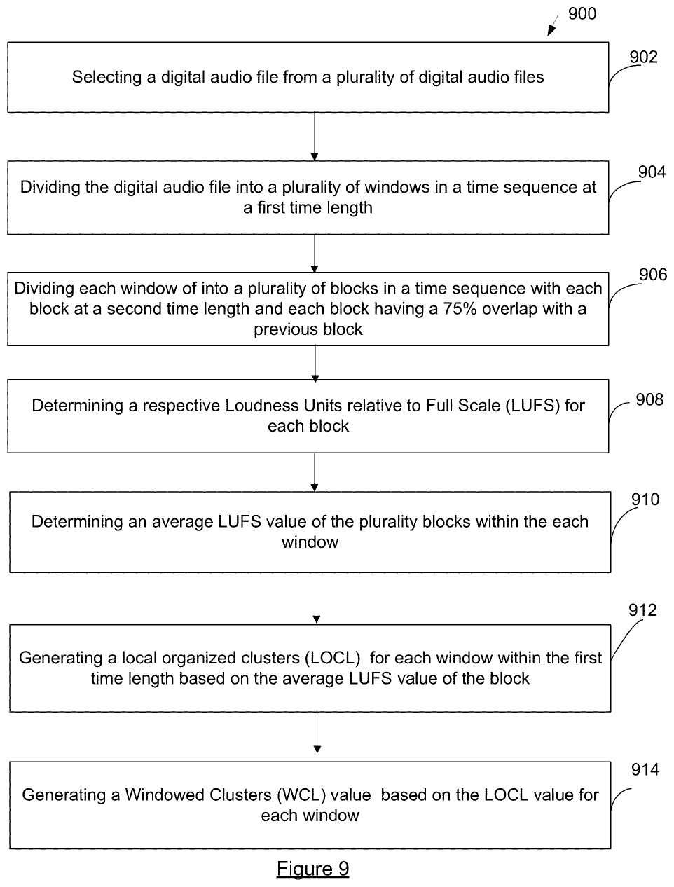

In some examples, the processor 102 is configured to implement a digital audio measurement Windowed Clusters (WCL) in method 900 illustrated in the flow chart of FIG. 9.

In some examples, the processor 102 is configured to implement a digital audio measurement Windowed Clusters (WCL) in method 900 illustrated in the flow chart of FIG. 9.

In method 900, the processor 102 is configured to measure momentary dynamics shift on a short-term basis, generating macrodynamic insights. The same baselines used by LOCL described in FIG. 2E above may be used for are used for WCL.

As illustrated in FIG. 9, at step 902, the processor 102 is configured to select a digital audio file from a plurality of digital audio files. The plurality of audio files may be in a PCM format, and may be music files for compiling a playlist. The digital audio file may be an audio data stream. The audio files may have different channel modes and frequency bands as described in methods 200-200D above.

At step 904, the processor 102 is configured to divide the audio file into a plurality of windows in a time sequence with each window at a first time length. The first time length may be any user-desired time length, such as 3 seconds or any time duration.

At step 906, with respect to each window of the plurality of windows, the processor 102 is configured to divide each window into a plurality of blocks in a time sequence with each block at a second time length and each block having a 75% overlap with a previous block. The second time length may be any user-desired time length, such as 400 ms, or any time duration less than the first time length.

At step 908, the processor 102 is configured to determine a Loudness Unit relative to Full Scale (LUFS) value for each block. The LUFS for each block can be an ungated LUFS.

At step 910, the processor 102 is configured to determine an average LUFS value of the blocks within the each window as baseline value.

At step 912, the processor 102 is configured to generate a local organized clusters (LOCL) for each window within the first time length in view of the average LUFS value of the blocks within that window, in the same manner as step 210d in method 200D as described above.

At step 914, the processor 102 is configured to generate a Windowed Clusters (WCL) value based on the LOCL value for each window. Other measurements are also derived from the LIV values for each window. In some examples, the LUFS readings for all the blocks in a single window can be averaged to create a value for the window. The values for all the windows are then used to determine the measurements for the entire algorithm, including the mean, deviation, quiet marker, loud marker, etc.

In some examples, Windowed Clusters (WCL) may include WML that measures momentary loudness distributions within short-term windows, then average those readings. WML allows to analyze how momentary dynamics shift in a macrodynamic context. With respect to WML, in method 900, each window at a first time length is 3 s, and each block has a second time length of 400 ms.

In some examples, the processor 102 is configured to process the digital audio file using user preferences or user-defined parameters for optimal playback within a plurality of audio files. For example, users can be provided with a library of songs that fit their defined parameters of bass intensity, high-frequency density, sibilance, perceived loudness, perceived impact, perceived textural impact, macrodynamic profile, or any combination of these or similar parameters that serve as representations of a audio file's perceived characteristics. For example, an audio file can be processed either via digital signal processing to modify sonic characteristics or rendering the file for playback via sequencing, compiling, normalizing, or grouping the audio file within the plurality of audio files. The user-defined parameters may include: tempo/beats-per-minute, genre and subgenre, lyrical content, mood-user-defined or defined by a combination of measured characteristics made to represent a “mood”, key or pitch, spectral characteristics including bass intensity, midrange intensity, high-frequency density, and sibilance, and dynamics characteristics including perceived loudness, perceived impact, dynamic range.

In some examples, the processor 102 is configured to associate or process the audio file for integration with external references based on the generated indicator(s). For example, if the suite of algorithms analyzed a plurality of digital audio files and generated indicators for each algorithm including LIV, RIV, TIV, LOCL, LOCL-MT, LOCL-ST and frequency-based LOCL for each digital audio file or song, the digital audio files can be processed for optimal playback in a variety of real-world environments or circumstances. For example, songs can be optimized for playback based on a reference input from: heart-rate monitors, e.g., a playlist can be curated to encourage or discourage intensity during physical activity based on a user's heart rate, provided to the processor 102 by an external device; and user-defined parameters associated with their mood or emotional state. For example, a user may create parameters to sequence quiet music for bedtime.

In some examples, the processor 102 is configured to process the audio file based on a user-defined profile for optimal playback. For example, the processor 102 can use measurements for each measured point to use as “targets”, and can process the digital audio file to hit those target figures. For example, the processor 102 may use song A to “learn” and subsequently process song B in order for song B to be perceived in a similar manner to song A.

In some examples, the processor 102 is configured to associate the plurality of digital audio files with their respective performance upon one or more digital consumption platforms. For example, the processor 102 may analyze a vast library of songs and associating their measurements with real-world information such as the audio file's performance upon digital consumption platforms such as Spotify or Tidal: user engagement, skip rate or degradation of a user's interest, playlist placement, stream count, duration, or mood tag.

In addition, the processor 102 is configured to analyze a plurality of digital audio files, such as a library of songs, using machine learning and apply LIV, RIV, TIV, LOCL, LOCL-MT, LOCL-ST or frequency-based LOCL measurements of the vast library in order to create “ideal” or “typical” profiles for specific genres, moods, or any user-defined parameters. For example, the processor 102 may analyze 100,000 rock songs using LIV, RIV, TIV, LOCL, LOCL-MT, LOCL-ST or frequency-based LOCL and can be sorted based on stream count, user engagement, skip rate or degradation of a user's interest, playlist placement, and/or duration. The processor 102 can then generate a “target profile” from the plurality of audio files' measurements that is associated with high or low stream counts, user engagement, etc.

The indicator of an audio file can be correlated with the file's performance on streaming platforms or consumer playback devices. For example, for an individual or for consumers at large. For example, the indicator can be correlated with any or all of:
the file's skip rate(s), or degradation of a user's interest
the average duration of consumer playback as a percentage of the file's total duration or as a unit of time
the file's placement in a plurality or sequence of audio files
the file's stream or play count
the file's release date
the local time and date at which the file is typically played
the location where the file is played
the file's tempo or beats-per-minute
the file's integrated conventional loudness (integrated LUFS)
the file's LRA (loudness range)
the author, publisher, or any contributing party credited for the audio file.

The indicator can be used alongside health monitoring devices such as heart-rate and blood pressure monitors. For example, by creating an individual schema for a user, the indicator of an audio file can correlate the user's definition of “calming” with a range of indicators.

In practice, the heart rate, blood pressure, or similar monitoring device can be used to trigger certain playlists for various health or wellness-oriented outcomes. For example, if a user's heart rate or blood pressure rises above a defined level, a system can play audio that the user will perceive as calming or relaxing, aiding in de-escalating the user's heart rate or blood pressure.

In a similar fashion, if the user is engaged in an activity that requires a periodic or constant physical energy expenditure from the user (exercise, for example), the system will be able to play music that the user defines as “exciting” or “energetic”, aiding in escalating the user's heart rate.

In some examples, the indicator may be used to curate playlists for interval-based activities such as interval training (HIIT or high-intensity interval training). For example, if a user's qualification of “intense” or “energetic” has been correlated with Breakneck Dynamics' measurements or if the system has stored the user's individual schema, the system will be able to identify and sequence audio files that meet specific criteria for Intensity (high, low, and everything in between) and Duration based on the user's desired interval structure.

In some examples, the indicator may be used to indicate higher yields on user playlists, perception of a better mood or playing music in sync with the activity a user currently engaging (e.g. HIIT). The indicator may be used to automatically generate a playlist by capturing user data while playing tracks or playlists and simultaneously recording the actions of the user. Actions of the user may include skip, thumbs down, favoriting, play more like this track, play more like this playlist, create more for this activity, etc.

In practice, the user would not be required to keep track of their interval structure via a stopwatch, screen, or any similar visual aid because the playlist would provide the user with the necessary information regarding the amount of intensity that the user should be expending at a given time.

In some examples, the indicator may be used to analyze audio files and to assess them based on a comparative analysis of their measurements versus a user-defined or program-defined “target” range of indicators. Based on the differences between the measured audio files' data points and the “target” range of measurements, machine learning-powered recommendations can be made and provided to users or an artificial intelligence to modify the measured audio files in order to better match or complement the “target” range.

For example, the processor 102 may analyze an audio file and compare its indicator to a “target” range of indicators of popular songs in the audio file's genre and subgenre.

Based on the outputs of the system 100 that makes recommendations based on the differences between a “subject” track and a “target” range of indicators, the processor 102 can be configured, such as using AI, to apply digital signal processing techniques to optimize an audio file for playback. This can be implemented using sophisticated feedback loops—the system can better optimize for the given targets as it processes more data.

For example, the processor 102 may be configured to modify an audio file along with a “target” range of indicators. The processor 102 can then modify the audio file's sonic characteristics to sit within or close to the boundaries of the “target” range.

The intention for the AI's modification of the “subject” file may be any or all of:
optimization for playback on consumer devices or systems
optimization for playback within a plurality of audio files
optimization for playback to match a user's listening preferences
optimization for playback to complement visual media
normalization

The audio files may be assessed, based on the their indicators, for purposes such as any or all of:
Scoring or Grading
Recommendations for modification
Categorization or Compilation.

In some examples, with a large number indicators of audio files stored, the processor 102 is configured to identify files that are within (or close) to a defined “target” range.

For example, a user may be looking for a TV show to play while falling asleep. The processor 102 can identify and display TV shows that sport soundtracks which sit with a range of BD measurements that indicate a constant or controlled macrodynamic profile (no excessive perceived sonic impact or loudness) to minimize excessive sensory stimulation from the TV.

The purpose of BD-based identification may be any or all of:
Identifying audio files within a user or program-defined set of parameters for compilation or categorization
Identifying audio that infringes on copyright ownership
Identifying outliers in a plurality of audio files

In some examples, the processor 102 may be configured to generate indicators on a set of audio files. The processor 102 is configured to sort the audio filed based on how similar the tracks are, for the purposes of categorization or compilation, based on the indicators.

The similarity factor can be automatically determined by the processor 102, or defined by a user prior to the sorting, and the processor 102 can optimize multiple factors at the same time.

The processor 102 can be used for curating songs for a specific application, such as playlist generation, or can be used for purely data-driven analysis of audio. Processor 102 is configure to learn to generate highly sophisticated track groupings and identify new similarities or patterns in tracks which may not be apparent to human observers.

The units described as separate parts may or may not be physically separate, and parts displayed as units may or may not be physical units, may be located in one position, or may be distributed on a plurality of network units. Some or all of the units may be selected according to actual requirements to achieve the objectives of the solutions of the embodiments.

In addition, functional units in the example embodiments may be integrated into one processing unit, or each of the units may exist alone physically, or two or more units are integrated into one unit.

When the functions are implemented in the form of a software functional unit and sold or used as an independent product, the functions may be stored in a computer-readable storage medium. Based on such an understanding, the technical solutions of example embodiments may be implemented in the form of a software product. The software product is stored in a storage medium, and includes several instructions for instructing a computer device (which may be a personal computer, a server, or a network device) to perform all or some of the steps of the methods described in the example embodiments. The foregoing storage medium includes any medium that can store program code, such as a Universal Serial Bus (USB) flash drive, a removable hard disk, a read-only memory (ROM), a random access memory (RAM), a magnetic disk, or an optical disc.

In the described methods or block diagrams, the boxes may represent events, steps, functions, processes, modules, messages, and/or state-based operations, etc. While some of the example embodiments have been described as occurring in a particular order, some of the steps or processes may be performed in a different order provided that the result of the changed order of any given step will not prevent or impair the occurrence of subsequent steps. Furthermore, some of the messages or steps described may be removed or combined in other embodiments, and some of the messages or steps described herein may be separated into a number of sub-messages or sub-steps in other embodiments. Even further, some or all of the steps may be repeated, as necessary. Elements described as methods or steps similarly apply to systems or subcomponents, and vice-versa. Reference to such words as “sending” or “receiving” could be interchanged depending on the perspective of the particular device.

The described embodiments are considered to be illustrative and not restrictive. Example embodiments described as methods would similarly apply to systems or devices, and vice-versa.

The various example embodiments are merely examples and are in no way meant to limit the scope of the example embodiments. Variations of the innovations described herein will be apparent to persons of ordinary skill in the art, such variations being within the intended scope of the example embodiments. In particular, features from one or more of the example embodiments may be selected to create alternative embodiments comprised of a sub-combination of features which may not be explicitly described. In addition, features from one or more of the described example embodiments may be selected and combined to create alternative example embodiments composed of a combination of features which may not be explicitly described. Features suitable for such combinations and sub-combinations would be readily apparent to persons skilled in the art. The subject matter described herein intends to cover all suitable changes in technology.

What is claimed is:

1. A method comprising:
dividing, by a processor, a digital audio file into a plurality of blocks in a time sequence at a first time length;
determining, by the processor, a respective Loudness Units relative to Full Scale (LUFS) for each block;
determining, by the processor, a difference between the LUFS of each block with a reference value; and
generating, by the processor, an indicator from one or more of the differences of the plurality of blocks within a second time length.

2. The method of claim 1, further comprising processing, by the processor, the digital audio file based on the indicator among a plurality of audio files.

3. The method of claim 2, wherein processing the digital audio file comprises rendering the audio file for playback among the plurality of the audio files.

4. The method of claim 2, wherein processing the digital audio file comprises sequencing or grouping of the audio file for among the plurality of digital audio files.

5. The method of claim 1, wherein the first time length is 400 ms.

6. The method of claim 1, wherein the first time length is 50 ms.

7. The method of claim 1, wherein the second time length is 3 seconds.

8. The method of claim 1, wherein the second time length is 10 seconds.

9. The method of claim 1, wherein the second time length is an entire duration of the digital audio file.

10. The method of claim 5, wherein each block overlaps with a next block in the time sequence by 75% of the first time length.

11. The method of claim 10, wherein the next block starts 100 ms from a start time of each block.

12. The method of claim 5, wherein values of the LUFS are ungated, and the reference value comprises a LUFS of a subsequent block of each block.

13. The method of claim 10, wherein the reference value comprises a baseline value of the digital audio file which is an average LUFS in a third time length.

14. The method of claim 13, wherein the third period is 3 seconds.

15. The method of claim 13, further comprising comparing the LUFS of each block to the baseline value and determining a difference between the LUFS for each block and the baseline value, wherein the LUFS is gated.

16. The method of claim 15, further comprising separately generating a first average of the difference between the baseline value and LUFS values greater than the baseline value, and a second average of the difference between the baseline value and the LUFS values lower than the baseline value.

17. The method of claim 6, wherein the LUFS are ungated, and the reference value comprises a LUFS of a subsequent block of each block.

18. The method of claim 1, wherein the first and second average values represent a local organized clusters (LOCL) value of the digital audio file.

19. The method of claim 1, wherein the indicator is a mean value of the one or more of the differences.

20. The method of claim 1, wherein the indicator indicates a relative level of perceived impact from the digital audio file.

21. The method of claim 1, wherein the indicator indicates a relative level of perceived real impact value from the digital audio file.

22. The method of claim 1, wherein the indicator indicates a relative level of perceived textural impact value from the digital audio file.

23. The method of claim 1, wherein the indicator indicates a relative level of local organized clusters (LOCL) of the digital audio file.

24. The method of claim 23, wherein the indicator comprises one or more local organized clusters (LOCL) analysis comprising one or more of, within the second time length: a Standard Deviation of LUFS, a measures of average LUFS, a comparative analysis of LUFS, or a distribution analysis of LUFS.

25. The method of claim 1, wherein processing the digital audio file comprises re-mastering the digital audio file with less compression and saturation to allow for more momentary dynamic variance.

26. The method of claim 2, further comprising compiling a playlist comprising the plurality of audio files.

27. The method of claim 1, wherein the digital audio file contains PCM audio data.

28. The method of claim 2, further comprising outputting or visualizing the indicator.

29. The method of claim 1, wherein the indicator is generated in real time.

30. The method of claim 1, wherein the digital audio file is associated with a user's preference comprising a user-defined mood tag.

31. The method of claim 1, further comprising filtering, by the processor, the digital audio file in one or more frequency bands.

32. The method of claim 31, wherein the one or more selected frequency bands comprise one or more of: below 100 Hz, between 100 Hz and 2000 Hz, between 2000 Hz and 5000 Hz, or a between 5000 Hz and 12000 Hz.

33. The method of claim 32, wherein the indicator comprises one or more of: a low-frequency indicator for the low-frequency band, a mid-frequency indicator for the mid-frequency band, a high-frequency indicator for the high-frequency band, or a sibilance indicator for the sibilance frequency band.

34. The method of claim 33, further comprising processing, by the processor, the digital audio file based on the one or more of the low-frequency indicator, the mid-frequency indicator, the high-frequency indicator, or the sibilance indicator.

35. The method of claim 2, wherein processing the digital audio file comprises normalizing the digital audio file using attenuation or amplification so that the indicator is within a target range.

36. The method of claim 2, wherein processing the digital audio file comprises spectral equalization or spectral dynamics for increasing or decreasing perceived loudness, envelope filtering, transient suppression, transient enhancement, frequency-based dynamics processing comprising high-frequency limiting or high-frequency expansion, or multiband compression or expansion, so that the digital audio file achieves a target indicator.

37. The method of claim 36, wherein spectral equalization or spectral dynamics comprises one or more of: resonance suppression, high-frequency limiting, or low-frequency compression or expansion.

38. The method of claim 1, further comprising playing back the digital audio file at a user-defined level on a digital streaming platform.

39. The method of claim 1, further comprising processing digital audio files with one or more user defined parameters comprising bass intensity, high-frequency density, sibilance, perceived loudness, perceived impact, perceived textural impact, macrodynamic profile, tempo or beats-per-minute, genre or subgenre, lyrical content, mood defined by the user or defined by a combination of measured characteristics, key, spectral characteristics comprising bass intensity, midrange intensity, high-frequency density, sibilance, or dynamics characteristics.

40. The method of claim 2, wherein processing the digital audio file comprises sequencing or grouping of the digital audio file among the plurality of digital audio files based on real impact values, textural impact value, or quiet or loud markers of local organized clusters of the plurality of the digital audio files.

41. The method of claim 1, further comprising associating the digital audio file for integration with an external reference based on the indicator.

42. The method of claim 2, wherein processing the digital audio file is based on a user-defined profile.

43. The method of claim 1, further comprising associating, by the processor, the plurality of digital audio files with their respective performance upon one or more digital consumption platforms.

44. The method of claim 1, further comprising analyzing, by the processor, the plurality of digital audio files using machine learning.

45. The method of claim 2, wherein processing the digital audio file comprises modifying the digital audio file so that the indicator is within a target range.

46. The method of claim 1, further comprising associating the indicator of the digital audio file with one or more qualifiers.

47. The method of claim 36, wherein the target indicator is user specified or matches one or more indicators or the plurality audio files.

48. The method of claim 1, wherein each block has a size of an entire block, a half, quarter, 8th, 16th, 32nd, and 64th notes.

49. A method comprising:
dividing, by a processor, a digital audio file into a plurality of windows in a time sequence at a first time length;
dividing, by the processor, each of the plurality windows into a plurality of blocks in a time sequence at a second time length;
determining, by the processor, a respective Loudness Units relative to Full Scale (LUFS) for each of the plurality blocks;
determining, by the processor, a difference between the LUFS of each of the plurality blocks with a reference value; and
generating, by the processor, a Linear Impact (LIV) value for each of the plurality of the windows.

50. The method of claim 36, wherein the first time length is 3 seconds.

51. The method of claim 49, wherein the second time length is 400 ms.

52. The method of claim 49, wherein the reference value is a LUFS of a next block of the each of the plurality blocks.

53. The method of claim 49, further comprising generating one or more indicators within a third time length based on the LIV value of the each of the plurality of windows.

54. A method comprising:
dividing, by a processor, a digital audio file into a plurality of windows in a time sequence at a first time length;
dividing, by the processor, each of the plurality windows into a plurality of blocks in a time sequence at a second time length and each of the plurality blocks having a 75% overlap with a previous block;
determining, by the processor, a respective Loudness Units relative to Full Scale (LUFS) for each of the plurality blocks;
determining, by the processor, an average LUFS value of the plurality blocks within the each of the plurality of window; and
generating, by the processor, a local organized clusters (LOCL) for each of the plurality of windows within the first time length based on the average LUFS value of the plurality of blocks for each of the plurality of the windows.

55. The method of claim 36, wherein the first time length is 3 seconds.

56. The method of claim 36, wherein the second time length is 400 ms.

57. The method of claim 36, further comprising generating a Windowed Clusters (WCL) value based on the LOCL value for each of the plurality of windows.
